(19) United States
(12) Patent Application Publication
(10) Pub. No.: US 2011/0147230 A1
(43) Pub. Date: Jun. 23, 2011

(54) Film Removal

(75) Inventors: James D. Reed, Findlay, OH (US); Wenming Wang, Toledo, OH (US)

(73) Assignee: First Solar, Inc., Perrysburg, OH (US)

(21) Appl. No.: 12/966,472

(22) Filed: Dec. 13, 2010

Related U.S. Application Data
(60) Provisional application No. 61/288,079, filed on Dec. 18, 2009.

(51) Int. Cl. B08B 7/00; H01L 21/306; H01L 21/304; B24B 1/00; B24B 7/00

(52) U.S. Cl. 205/662; 204/242; 204/199; 451/57; 451/64

(57) ABSTRACT

A method of removing coating from a substrate may include contacting a portion of coating on a surface of a substrate to an acid.

### CLAIM FOR PRIORITY

This application claims priority under 35 U.S.C. §119(e) to U.S. Provisional Patent Application Ser. No. 61/288,079 filed on Dec. 18, 2009, which is hereby incorporated by reference.

### TECHNICAL FIELD

The present invention relates to the production of photovoltaic modules and methods of recycling the active elements.

### BACKGROUND

Photovoltaic modules can include semiconductor material deposited over a substrate. It is sometimes necessary to remove a deposited material from a substrate.

### DESCRIPTION OF DRAWINGS

FIG. 1 is a schematic of a coated substrate in an acid solution.

FIG. 2 is a schematic of a coated substrate passing through an acid deposition chamber.

FIG. 3 is a schematic of a coated substrate passing through a chamber including an abrasive material.

FIG. 4 is a schematic of a coated substrate passing through an acid deposition chamber including an abrasive material.

FIG. 5 is a schematic of a coated substrate in an acid solution, connected to a power source.

FIG. 6 is a schematic of multiple coated substrates in an acid solution, connected to a power source.

FIG. 7 is a schematic of a coated substrate in an acid solution, connected to a power source.

### DETAILED DESCRIPTION

Photovoltaic modules can include one or more coating layers created adjacent to a substrate. Layers can be created by forming or depositing material adjacent to the substrate. For example, a photovoltaic module may contain a semiconductor absorber layer deposited over a semiconductor window layer. The semiconductor window and absorber layers may include cadmium. For example, the semiconductor window layer may include a cadmium sulfide, and the semiconductor absorber layer may include a cadmium telluride. A transparent conductive oxide (TCO) coating can be deposited on the substrate prior to deposition of the semiconductor window and absorber layers. The TCO coating may include cadmium and/or tin. For example, the TCO coating may include a cadmium stannate. Each layer may in turn include more than one layer or film. Additionally, each layer can cover all or a portion of the device and/or all or a portion of the layer or substrate underlying the layer. For example, a “layer” can mean any amount of any material that contacts all or a portion of a surface.

It is sometimes desirable to remove one or more coating layers from the surface of a substrate. The coating can be removed by a chemical process, an electrochemical process, a mechanical process, or any combination thereof. A substrate with coating (e.g., cadmium stannate) may be etched by contacting it with an acidic substance. The acidic substance can be diluted. For example, the acidic substance can include about 100 mL of water and about 2.5 mL of any suitable hydrochloric acid, including, for example, 25% or 35% hydrochloric acid. The coated substrate may be immersed completely within the acidic substance, during which process one or more portions of coating may be separated or etched from the substrate. The etch rate may be increased using a variety of electrochemical and/or mechanical techniques.

Before, during, or after contacting the coated substrate with the acidic substance, the coated surface of the substrate may be contacted with an appropriate scrubbing tool to increase the etch rate. The scrubbing tool may include any suitable device or material, including, for example, an abrasive pad or brush, including, for example, a nylon brush. The addition of a mechanical scrubbing step can eliminate the need for elevated acid temperatures (i.e., when a hydrochloric acid solution is used), and reduce the overall time needed to remove undesired coating from the substrate. The scrubbing step may be executed without substantially scratching the substrate.

The etch rate may also be increased through electrochemical means. For example, a cadmium stannate TCO may be electrically connected to a live DC power source. The TCO may act as a cathode, during which process hydrogen evolution may occur, leading to reactive hydrogen species on the TCO. The cadmium stannate may disproportionate and separate from the substrate. The electrochemical leaching may occur at any suitable temperature range, including, for example, above about 60° C.

It should be noted that the methods and apparatuses discussed herein may be suitable for removing various coatings and/or chemicals from various types of surfaces or substrates. For example, the methods and apparatuses discussed herein can be used to remove unwanted coatings or chemicals from large reaction shields or flat screens. A substrate treated using the methods and apparatuses described herein may be reused, washed, or recycled.

In one aspect, a method of removing coating from a substrate may include contacting a portion of coating on a surface of a substrate to an acid. The coating may include cadmium. The method may include contacting the portion of coating on the surface of the substrate with an abrasive material. The method may include removing a portion of the coating from the substrate.

The acid may include a hydrochloric acid solution. The acid may include a hydrochloric acid concentration of more than about 10%, more than about 20%, or less than about 30%. The step of contacting a portion of coating on a surface of a substrate to an acid may include submerging at least a portion of the substrate into the acid. The step of contacting a portion of coating on a surface of a substrate to an acid may include directing the acid toward the surface of the substrate. The step of directing the acid may include directing the acid through a nozzle pointed at the surface of the substrate. The coating may include tin. The coating may include a cadmium stannate. The substrate may include a glass, for example, a soda-lime glass. The method may include connecting a power source to the substrate and to an anode material, and applying a current and a voltage. The power source may include a DC source. The current may be in a range of about 0.2 A to about 0.6 A. The voltage may be in a range of about 4 V to about 12V. The anode material may include a stainless steel, a graphite, or a titanium alloy. The method may include fixing the substrate in a holder. The holder may be proximate to the anode material. At least a portion of the holder may contact the acid. The holder may include a conductive material. The holder may include a metal-mesh basket. The method may include rotating the metal-mesh basket. The acid may include a hydrochloric acid concentration in a range of about 0.1% to about 1.0%. The step of contacting a portion of coating on a surface of a substrate to an acid may occur at a temperature of less than about 60° C., or less than about 50° C.

In another aspect, a method of removing coating from a substrate may include contacting a portion of coating on a surface of a substrate to an acid. The coating may include tin. The method may include contacting the portion of coating on the surface of the substrate with an abrasive material. The method may include removing a portion of the coating from the substrate.

The acid may include a hydrochloric acid solution. The acid may include a hydrochloric acid concentration of more than about 10%, more than about 20%, or less than about 30%. The step of contacting a portion of coating on a surface of a substrate to an acid may include submerging at least a portion of the substrate into the acid. The step of contacting a portion of coating on a surface of a substrate to an acid may include directing the acid toward the surface of the substrate. The step of directing the acid may include directing the acid through a nozzle pointed at the surface of the substrate. The coating may include cadmium. The coating may include a cadmium stannate. The substrate may include a glass, for example, a soda-lime glass. The step of contacting a portion of coating on a surface of a substrate to an acid may occur at a temperature of less than about 60° C., or less than about 50° C.

In one aspect, an apparatus for removing coating from a substrate may include a reservoir for containing an acid to be contacted with a coating on a surface of a substrate. The apparatus may include an abrasive material proximate to the reservoir to contact the coating.

The abrasive material may include a brush. The brush may include nylon. The abrasive material may include a pad. The apparatus may include an anode. The apparatus may include a cathode. The cathode may be configured to receive a substrate. The apparatus may include a power source connecting the anode to the cathode. The cathode may include a holder. The holder may include a conductive material. The holder may include a metal-mesh basket. The apparatus may include a motor. The motor may be configured to rotate the metal-mesh basket. The anode may be positioned within the reservoir, in at least partial contact with the acid. The anode may be positioned proximate to the cathode. The anode may include a stainless steel, a titanium alloy, or a graphite. The power source may include a DC power source.

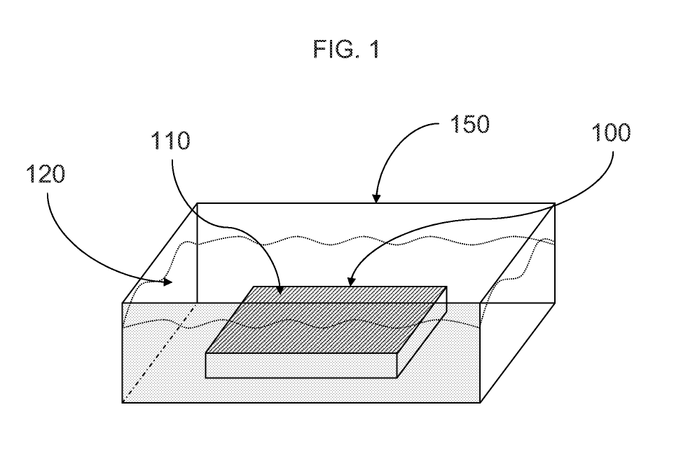

Referring to FIG. 1, substrate 100 can be contacted to or immersed within an acid solution 120. Acid solution 120 may include any suitable acid. Acid solution 120 may include any suitable hydrochloric acid, which may include any suitable hydrochloric acid concentration, including, for example, more than about 10% hydrochloric acid, more than about 20% hydrochloric acid, or less than about 30% hydrochloric acid. For example, acid solution 120 may include 25% hydrochloric acid. Substrate 100 can include any suitable substrate material, including glass, for example, soda-lime glass. Substrate 100 can contain at least a portion of coating, including, for example, a coating layer 110. Coating layer 110 can include a TCO layer, including, for example, a cadmium stannate (or cadmium and tin) layer. Coating layer 110 may include any other suitable TCO material, including, for example, tin oxide, indium tin oxide, or cadmium tin oxide. Acid solution 120 can react with coating layer 110, causing one or more portions of coating layer 110 to disassociate and separate from substrate 100.

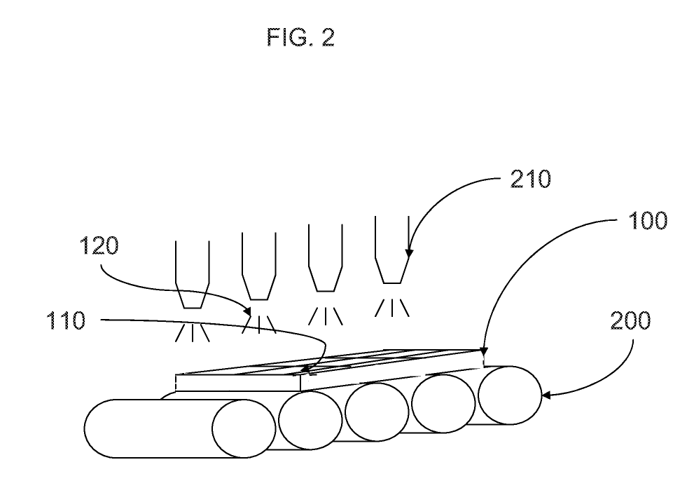

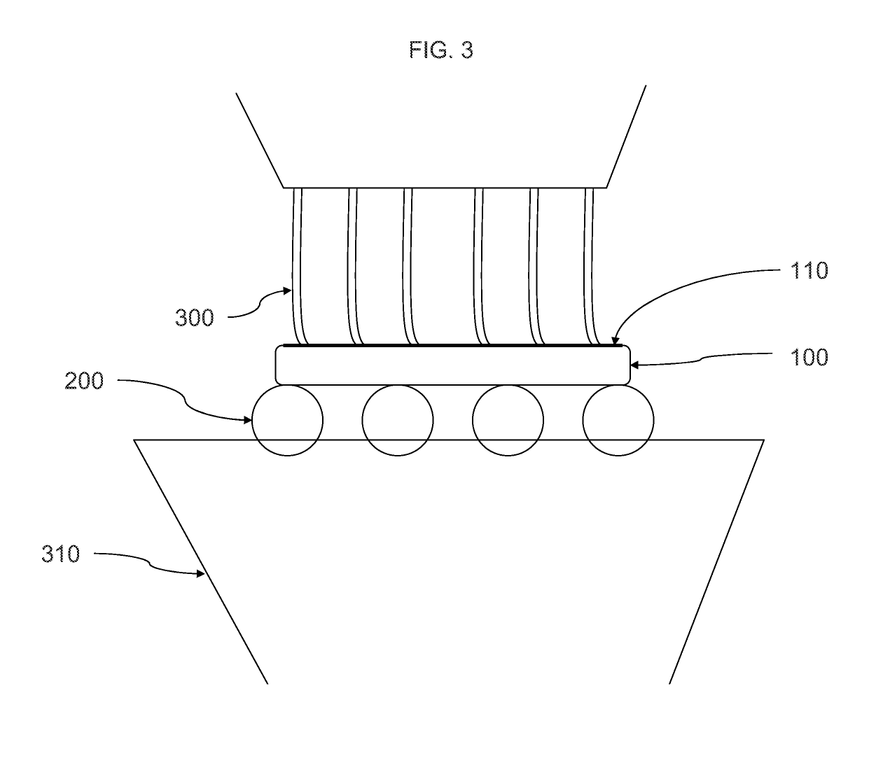

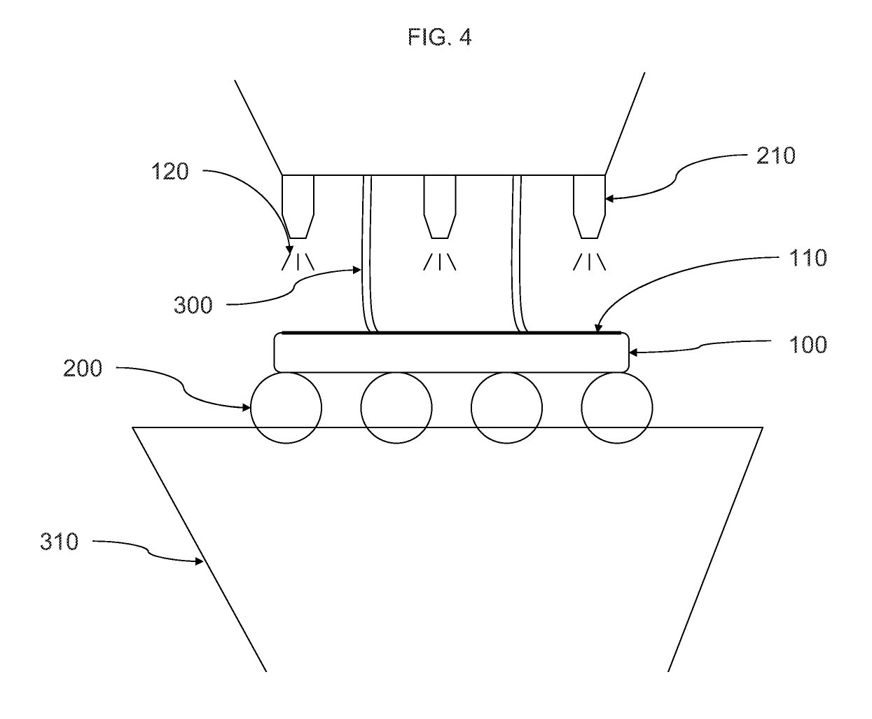

Acid solution 120 may be contacted to coating layer 110 of substrate 100 using any suitable means. For example, as shown in FIG. 1, substrate 100 may be placed in a container 150 including acid solution 120. Substrate 100 may be fully or partially submerged within container 150. Alternatively, referring now to FIG. 2, substrate 100 can be passed through a deposition chamber via rollers 200 and exposed to acid solution 120 (e.g., a hydrochloric acid solution) via one or more deposition nozzles 210. Any excess acid solution 120 and/or removed coating layer 110 may be collected via drainage basket 310 positioned beneath substrate 100, as depicted in FIGS. 3 and 4.

The disassociation and removal of coating layer 110 can be expedited through contacting coating layer 110 of substrate 100 with a scrubbing tool. The scrubbing tool may include any suitable device or material, including, for example, an abrasive pad, or a brush. The scrubbing may occur before, during, or after exposure of coated substrate 100 to acid solution 120, and may include any suitable scrubbing technique, and may occur for any suitable duration. The scrubbing may be targeted to focus on any one or more specific areas of coating layer 110 on substrate 100. Referring to FIG. 3, by way of example, substrate 100 may pass through a deposition chamber where one or more abrasive pads 300 may contact coating layer 110 of substrate 100, facilitating and expediting removal of one or more portions of coating layer 110. The scrubbing may also take place during exposure of coated substrate 100 to acid solution 120. Referring to FIG. 4, by way of example, substrate 100 may pass through a deposition chamber where deposition nozzles 210 spray coating layer 110 of substrate 100 with acid solution 120, and one or more abrasive pads 300 contacts coating layer 110 during its exposure to acid solution 120. Any disassociated or removed portions of coating layer 110 may be collected in drainage basket 310 positioned underneath substrate 100. Drainage basket 310 may extend substantially beyond both ends of substrate 100 to ensure collection of coating material from substrate 100, as well as any excess acid solution 120. Drainage basket 310 may also extend vertically beyond a bottom plane of rollers 200 to ensure proper collection of any unwanted material. The addition of the scrubbing step can substantially reduce the amount of time needed to remove undesired coating from substrate 100, and may also reduce and/or eliminate the need for elevated acid temperatures (e.g., above about 60° C.). The scrubbing step may be executed without scratching the surface of substrate 100.

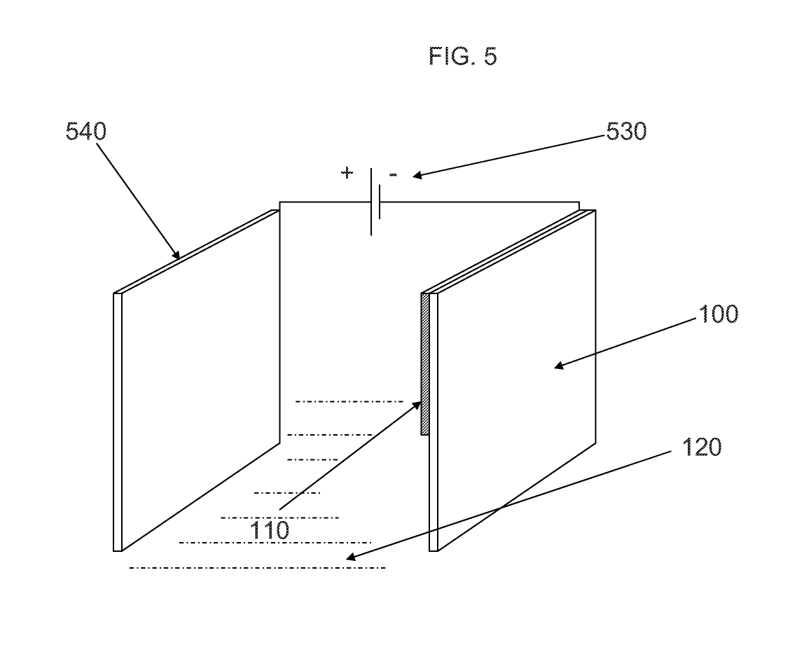

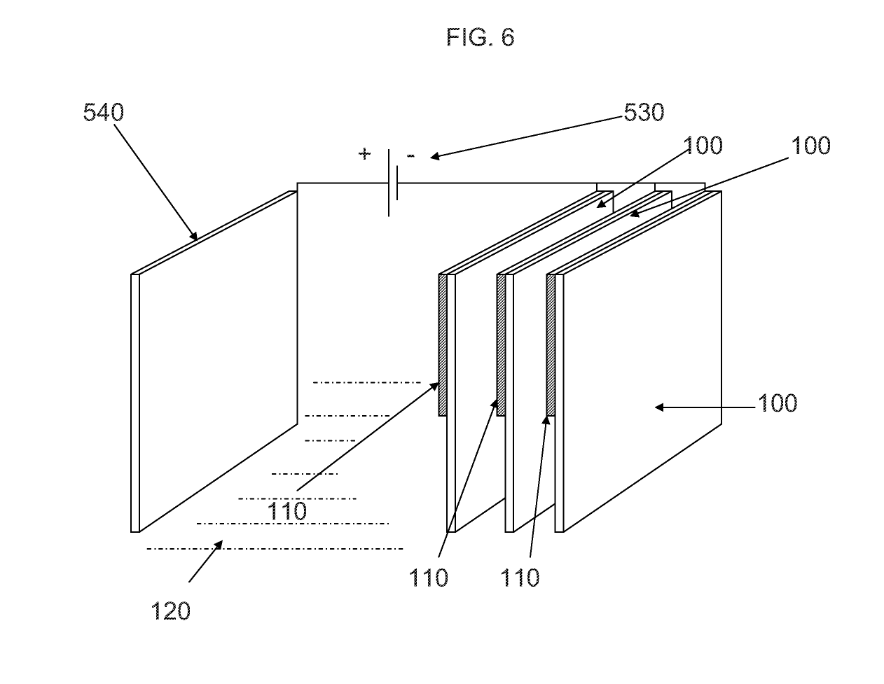

The removal of coating layer 110 may also be expedited by connecting coating layer 110 to a power source. Referring to FIG. 5, by way of example, coating layer 110 may be connected to a power source 530. Power source 530 can include any suitable power source, including, for example, a DC power source. An anode 540 can be connected to power source 530, permitting coating layer 110 to act as a cathode. Anode 540 can include any suitable material, including, for example, stainless steel, graphite, or titanium alloy. Substrate 100 with coating layer 110, and anode 540 can be placed in a metal-mesh basket and immersed into acid solution 120, or any other electrolytic substance, to induce an electrochemical leach. Substrate 100 with coating layer 110 may be scrubbed while immersed in the basket. Substrate 100 may also be scrubbed following the electrochemical leach altogether. Referring to FIG. 6, it is possible to electrochemically leach more than one coated substrate at a time. FIG. 6 depicts three substrates 100 with coating layers 110, connected to power supply 530. After contact with or submersion into acid solution 120 (or any other electrolytic substance), coating layer 110 can completely delaminate and dissolve, leaving the treated substrate intact. The treated substrate may be reused, washed, or recycled.

Acid solution 120 may include a hydrochloric acid, which may include any suitable hydrochloric acid concentration. For example, acid solution 120 may include a 25% hydrochloric acid solution. In the electrochemical leaching processes depicted in FIGS. 5 and 6, the hydrochloric acid concentration can be in the range of about 0.1% to about 1.0%, about 0.2% to about 0.9%, or about 0.4% to about 0.6%. Upon contacting or immersing a substrate 100 with a cadmium stannate coating layer 110 connected to a DC power source, the following reactions may take place:

(At the Cathode)

2H⁺+2e=2H (1)

Cd₂SnO₄+8H⁺+12Cl⁻+2e=2CdCl₄²⁻+SnCl₄²⁻+4H₂O (2)

SnCl₆²⁻+2e=SnCl₄²⁻+2Cl⁻ (3)

SnCl₄²⁻+2e=Sn+4Cl⁻ (4)

CdCl₄²⁻+2e=Cd+4Cl⁻ (5)

SnCl₆²⁻+2H=SnCl₄²⁻+2H⁺+2Cl⁻ (6)

(At the Anode)

Cl⁻+4H₂O═ClO₄⁻+8H⁺ (7)

2Cl⁻═Cl₂(aq) (8)

In another embodiment, coating layer 110 can include a tin oxide, in which case reaction (2) from above would become SnO₂+4H⁺+4Cl⁻+2e=SnCl₄²⁻+2H₂O.

Without being bound to any particular theory, at the cathode, tin(IV) is reduced to tin(II), which is soluble in hydrochloric acid solution, leading to the ultimate decomposition and dissolution of coating layer 110. Depending on the voltage of hydrochloric acid solution 120 (or any other electrolytic substance), both tin(II) and cadmium(II) may be further reduced to metallic form. In one sample test series, both coatings of tin oxide and cadmium stannate completely dissolved when contacted with a hydrochloric acid solution. Furthermore, a relatively low hydrochloric acid concentration was used, about 0.1% to about 1.0%. Testing showed that when cell voltage was controlled at around 10 V to about 11 V, the current was in the range of about 0.3 A to about 0.5 A. It should be noted, however, that the range of the current is not so limited. The current can be in any suitable range, including, for example, about 0.1 A to about 1.0 A, about 0.2 A to about 0.8 A, or about 0.3 A to about 0.5 A. For example, in one electrochemical leaching test, a current of about 0.4 A was observed, with a cell voltage of about 4.3 V. It should also be noted that the substrate can be contacted to or submerged in the hydrochloric acid solution (or any other electrolytic substance) for any suitable duration to remove the desired amount of coating, with or without the aid of a scrubbing tool. Testing indicated that submerging or contacting a coated glass substrate with hydrochloric acid for less than about 1 hour was suitable to cause the desired dissolution and decomposition of cadmium stannate from the substrate. Scrubbing the substrate may substantially reduce the time needed to achieve the desired dissolution and decomposition of coating from the substrate, as well as the temperature needed to facilitate dissolution. For example, the leaching may occur at a temperature of less than about 60° C., less than about 50° C., or at about 40° C. to about 60° C.

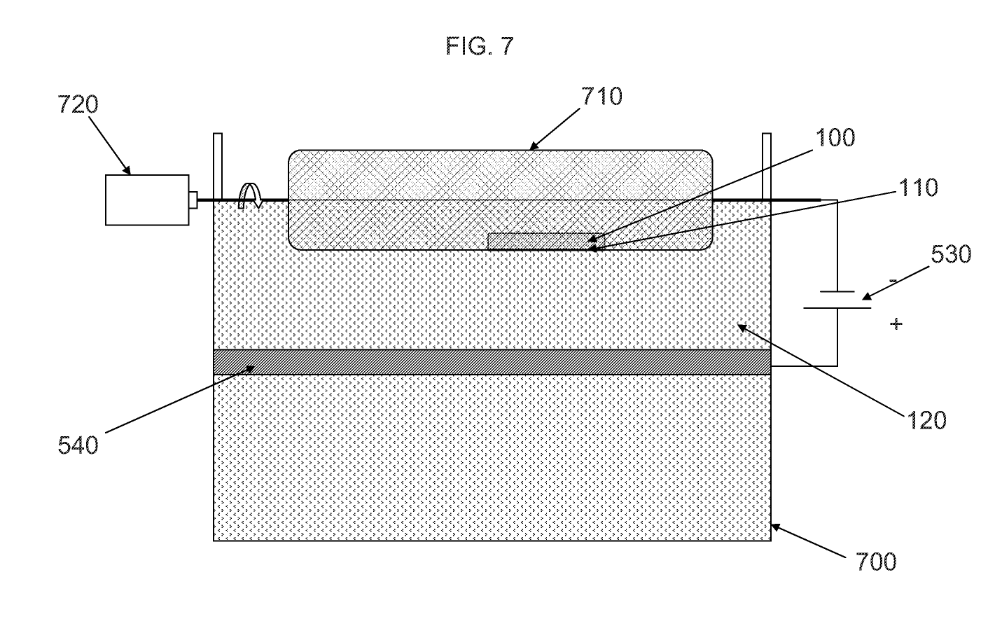

Referring to FIG. 7, an apparatus for electrochemically removing coating from a substrate can include a reservoir 700 which may contain acid solution 120 (or any other suitable electrolytic substance). A scrubbing tool may be positioned substantially proximate to the reservoir to scrub the substrate before, during, or after immersion into the reservoir. The scrubbing tool may be located substantially separate from the reservoir, in which case the scrubbing may be performed as a distinct step. A scrubbing tool may include any suitable material for scrubbing a coating off of a substrate, including, for example, a brush or a pad, or any combination thereof. The brush or pad may be substantially abrasive. Anode 540 can be placed in contact with acid solution 120. For example, anode 540 can be fully submerged within acid solution 120. Substrate 100 (with coating layer 110) can then be placed into contact with acid solution 120 proximate to anode 540. Substrate 100 can be fixed in a holder. The holder can contain a conductive material. For example, substrate 100 can be placed into metal-mesh basket 710, which upon making electrical contact with substrate 100 can serve as a cathode. The metal-mesh basket can include any suitable metal, including steel. A power source 530 can connect metal-mesh basket 710 (i.e., the cathode) to anode 540, and can supply electrical current to the components. A scrubbing tool may be used to facilitate the coating-removal process while substrate 100 is fixated within metal-mesh basket 710 or any other holder.

The apparatus can also include a motor 720 connected to metal-mesh basket 710. Motor 720 can rotate metal-mesh basket 710 to alter the position of coating layer 110 of substrate 100 relative to anode 540, to facilitate even dissolution and decomposition of coating layer 110. Motor 720 can be configured to rotate metal-mesh basket 710 clockwise, counter-clockwise or both, and at any suitable speed. For example, motor 720 can be configured to rotate metal-mesh basket 710 at a substantially slow rate.

Photovoltaic devices/modules fabricated using the methods and apparatuses discussed herein may be incorporated into one or more photovoltaic arrays. The arrays may be incorporated into various systems for generating electricity. For example, a photovoltaic module may be illuminated with a beam of light to generate a photocurrent. The photocurrent may be collected and converted from direct current (DC) to alternating current (AC) and distributed to a power grid. Light of any suitable wavelength may be directed at the module to produce the photocurrent, including, for example, more than 400 nm, or less than 700 nm (e.g., ultraviolet light). Photocurrent generated from one photovoltaic module may be combined with photocurrent generated from other photovoltaic modules. For example, the photovoltaic modules may be part of a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method of removing coating from a substrate, the method comprising the steps of:
contacting a portion of coating on a surface of a substrate to an acid, wherein the coating comprises cadmium or tin;
contacting the portion of coating on the surface of the substrate with an abrasive material; and
removing a portion of the coating from the substrate.

2. The method of claim 1, wherein the acid comprises a hydrochloric acid solution.

3. The method of claim 1, wherein the step of contacting a portion of coating on a surface of a substrate to an acid comprises:
submerging at least a portion of the substrate into the acid; or
directing the acid toward the surface of the substrate.

4. The method of claim 3, wherein the step of directing the acid comprises directing the acid through a nozzle pointed at the surface of the substrate.

5. The method of claim 1, wherein the coating comprises cadmium and tin.

6. The method of claim 1, wherein the substrate comprises a glass.

7. The method of claim 1, further comprising connecting a power source to the substrate and to an anode material, and applying a current and a voltage.

8. The method of claim 10, wherein the power source comprises a DC source.

9. The method of claim 10, wherein the current is in a range of about 0.2 A to about 0.6 A and the voltage is in a range of about 4 V to about 12 V.

10. The method of claim 10, wherein the anode material comprises a stainless steel, a graphite, or a titanium alloy.

11. The method of claim 10, further comprising fixing the substrate in a holder, wherein the holder is proximate to the anode material, and wherein at least a portion of the holder contacts the acid.

12. The method of claim 15, wherein the holder comprises a conductive material.

13. The method of claim 1, wherein the step of contacting a portion of coating on a surface of a substrate to an acid occurs at a temperature of less than about 60° C.

14. An apparatus for removing coating from a substrate, the apparatus comprising:
a reservoir for containing an acid to be contacted with a coating on a surface of a substrate; and
an abrasive material proximate to the reservoir to contact the coating.

15. The apparatus of claim 14, wherein the abrasive material comprises a brush or a pad.

16. The apparatus of claim 14, further comprising:
an anode;
a cathode, wherein the cathode is configured to receive a substrate; and
a power source connecting the anode to the cathode.

17. The apparatus of claim 16, wherein the cathode comprises a holder.

18. The apparatus of claim 17, wherein the holder comprises a conductive material.

19. The apparatus of claim 18, further comprising a motor, wherein the motor is configured to rotate the conductive material.

20. The apparatus of claim 16, wherein the anode is positioned within the reservoir proximate to the cathode.

21. The apparatus of claim 16, wherein the anode comprises a stainless steel, a titanium alloy, or a graphite.
